(19) United States
(12) Patent Application Publication
(10) Pub. No.: US 2013/0320994 A1
(43) Pub. Date: Dec. 5, 2013

(54) ELECTRODE TESTING APPARATUS

(71) Applicants: Kenneth G. BRITTAIN, Cottage Grove, MN (US); Sammuel D. Herbert, Woodbury, MN (US); Neil F. Diamond, Oakdale, MN (US)

(72) Inventors: Kenneth G. BRITTAIN, Cottage Grove, MN (US); Sammuel D. Herbert, Woodbury, MN (US); Neil F. Diamond, Oakdale, MN (US)

(73) Assignee: 3M Innovative Properties Company

(21) Appl. No.: 13/483,746

(22) Filed: May 30, 2012

(51) Int. Cl. G01R 31/02; G01R 27/08

(52) U.S. Cl. 324/537; 324/691

(57) ABSTRACT

An apparatus to infer the resistivity of an electrode by stimulating the electrode with a capacitively coupled signal, and processing the resultant signal with circuitry that produces a signal having an amplitude that is a function of the resistivity of the electrode.

### FIELD OF THE INVENTION

This invention relates generally to devices used for testing, for example in a manufacturing setting, touch panels, particularly matrix-type transparent mutual capacitive touch panels.

### BACKGROUND

Touch sensitive devices allow a user to conveniently interface with electronic systems and displays by reducing or eliminating the need for mechanical buttons, keypads, keyboards, and pointing devices. For example, a user can carry out a complicated sequence of instructions by simply touching an on-display touch screen at a location identified by an icon. Touch sensitive devices have two principle components: a touch panel, which is usually that part with which a user makes contact; and a controller, coupled to the touch panel, to decipher touches occurring thereon. Touch panels are typically comprised of an upper and lower arrays of transparent electrodes, arranged orthogonally to one another and separated by a dielectric. Touch panels may fail when resistivity on any one of the electrodes exceeds what the controller can accommodate.

### BRIEF SUMMARY

A circuit and device for inferring the resistance of an electrode by introducing a signal, via capacitive coupling, to a stimulation point of the electrode, and measuring a resultant signals at a measurement point on the electrode. A measurement circuit features a virtual ground amplifier circuit configured to produce a signal that has certain characteristics that are a linear function of the resistance of the electrode between the stimulation and measurement points. Electronics measure the characteristics, typically amplitude, and can infer therefrom the resistance of the electrode.

### BRIEF DESCRIPTION OF DRAWINGS

FIG. 1 is a schematic view of a touch device;

FIG. 2 is a schematic side view of a portion of a touch panel used in a touch device;

FIG. 3 is a circuit diagram of an electrode testing apparatus; and

FIG. 4 is a graph of a stimulating signal applied to an electrode, and corresponding signals at various points in the circuit of FIG. 3.

In the figures, like reference numerals designate like elements.

### DETAILED DESCRIPTION OF ILLUSTRATIVE EMBODIMENTS

Construction particulars of modern projected capacitive transparent touch screens, the type commonly used to overlay an electronic display and provide a user with touch-based interactivity, make evaluating and testing the touch panel components difficult after certain stages of the panel construction manufacturing process. For example, a projected capacitive touch screen stack may typically comprise upper and lower electrode arrays, orthogonally oriented to one another, and separated by a dielectric. After the stack is constructed, usually by a lamination process involving separate layers of materials, only one end of the electrodes of the upper or lower arrays may be available for physical electric connections. This limits the types of testing that may be applied to the touch screen stack, which is unfortunate because the types of materials used in such electrodes can fail in myriad ways, and some of these failure modes may not be detectable until the panel is coupled with a controller (which is typically late in the manufacturing process).

Traditional methods of touch panel testing would then involve coupling the individual arrays of the panel to a testing system and testing for certain basic failure scenarios existing between a stimulated electrode and a receive electrode (signals applied to the stimulated electrode capacitively coupling to the receive electrode at the point they cross over one another—also referred to as a node). Such existing testing approaches yield quite basic data, for example whether an electrode has a discontinuity (“open”) or is erroneously connected with another component of the panel (“short”). If an open condition is detected, further testing might give an indication of where the discontinuity exists, which may be used to improve manufacturing processes. If a short condition is detected, the applied signal will be significantly attenuated either on the other end of the stimulated electrode (if there is access to such) or on the receive electrode, or the applied signal may appear on multiple receive electrodes (if the short condition exists between the drive electrode and one of the receive electrodes of the other array). A short on the stimulated electrode may be somewhat more difficult to detect, but the simulated electrode may be treated as a receive electrode by essentially flipping the touch panel and stimulating electrodes previously associated with receives, and receiving on the electrodes previously associated with being stimulated.

Basic testing such as for opens and shorts will not reveal certain conditions associated with electrodes in a panel (or the tail to which the electrodes are bonded which then couples the electronics to the controller) that could be either indicative of likely subsequent failure or indicative of manufacturing defects. Such conditions may include unusual resistivity values. For example, in panels comprised of fine micro-wire patterns (see, for example, U.S. Pat. No. 8,179,381, “Touch Screen Sensor”), individual electrodes may comprise very fine features. The failure mode of these features may be such that they pass a basic open/short testing regime, but anomalies may be present when the resistivity values of particular electrodes, or portions of electrodes, are queried. This leads back to the earlier mentioned issue, however, which involves the difficulty of measuring resistivity of an electrode when one only has physical connection access to one side of that electrode.

This disclosure presents a novel apparatus and method to infer the resistivity of an electrode with a physical electrical connection to one point of the electrode, and a capacitively coupled connection to another point. With such apparatus and method, it is possible to infer relative or quantified resistivity values of electrodes a capacitive touch screen. These values could be used to identify panels having electrodes in a pre-failure state that would pass traditional open/short type quality control testing. Additionally, these values could be used to identify manufacturing defects that should be addressed. While this apparatus and method are presented in the context of testing a panel component of a touch-sensitive device (the device comprising both the panel along with controller electrics), there are other non-touch applications that will present themselves to those skilled in the art, where resistivity values may be needed but where it is not practical or feasible to physically electrically couple to both ends of the electrode under test. Such applications might include measuring and quantifying cross-talk field coupling; testing other types of capacitive-based sensors, such as membrane type capacitive switches or touch sensors; or testing electrodes in any application where there is only physical electrical coupling to one part of the electrode to be tested, and there is only capacitive coupling access to another point. Physical electrical coupling means electrical coupling by physical connection, rather than by capacitive coupling.

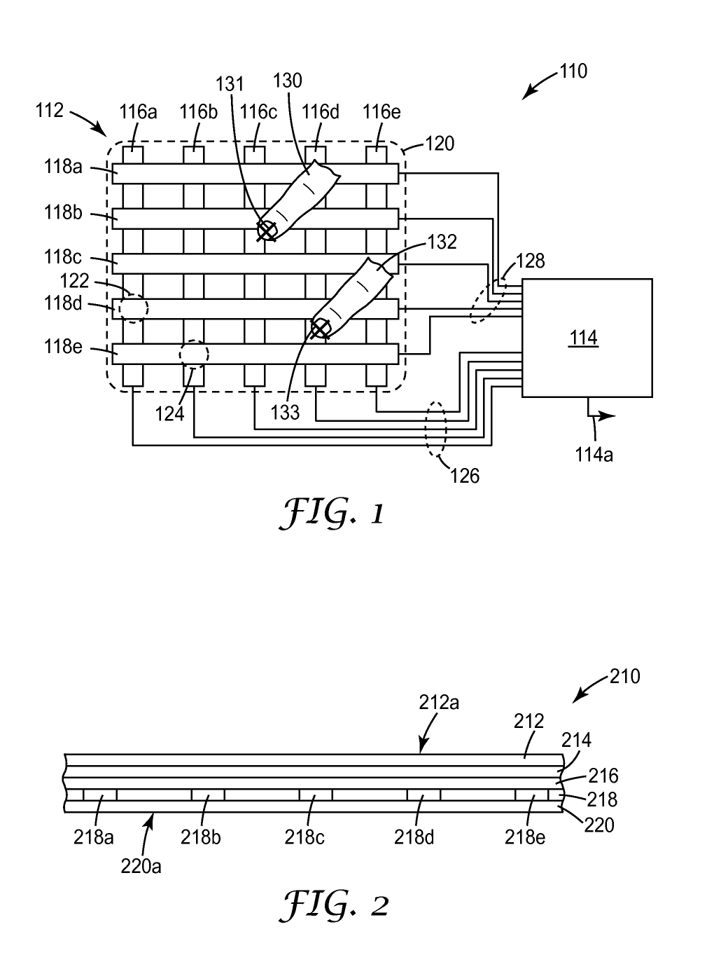

In FIG. 1, an exemplary touch device 110 is shown. The device 110 includes a touch panel 112 connected to electronic circuitry, which for simplicity is grouped together into a single schematic box labeled 114 and referred to collectively as a controller. The touch panel 112 is shown as having a 5×5 matrix comprised of a lower array of column electrodes 116a-e and an upper array of row electrodes 118a-e, but other numbers of electrodes and other matrix sizes can also be used. The panel 112 is typically substantially transparent so that the user is able to view an object, such as the pixilated display of a computer, hand-held device, mobile phone, or other peripheral device, through the panel 112. The boundary 120 represents the viewing area of the panel 112 and also preferably the viewing area of such a display, if used. The electrodes 116a-e, 118a-e are spatially distributed, from a plan view perspective, over the viewing area 120. For ease of illustration the electrodes are shown to be wide and obtrusive, but in practice they may be relatively narrow and inconspicuous to the user. Further, they may be designed to have variable widths, e.g., an increased width in the form of a diamond- or other-shaped pad in the vicinity of the nodes of the matrix in order to increase the inter-electrode fringe field and thereby increase the effect of a touch on the electrode-to-electrode capacitive coupling. In exemplary embodiments the electrodes may be composed of indium tin oxide (ITO), a network of fine micro-conductor wires, or other suitable electrically conductive materials. From a depth perspective, the column electrodes may lie in a different plane than the row electrodes (from the perspective of FIG. 1, the column electrodes 116a-e lie underneath the row electrodes 118a-e) such that no significant ohmic contact is made between column and row electrodes, and so that the only significant electrical coupling between a given column electrode and a given row electrode is capacitive coupling. In other embodiments, the row electrode and discreet column electrode components may be disposed on the same substrate, in the same layer, then bridging jumper electrodes configured to connect the discreet column electrode components (spaced apart from the column electrode by a dielectric) to thus form x- and y-electrodes using a substantially single layer construction. The matrix of electrodes typically lies beneath a cover glass, plastic film, or the like, so that the electrodes are protected from direct physical contact with a user's finger or other touch-related implement. An exposed surface of such a cover glass, film, or the like may be referred to as a touch surface. Additionally, in display-type applications, a back shield may be placed between the display and the touch panel 112. Such a back shield typically consists of a conductive ITO coating on a glass or film, and can be grounded or driven with a waveform that reduces signal coupling into touch panel 112 from external electrical interference sources. Other approaches to back shielding are known in the art. In general, a back shield reduces noise sensed by touch panel 112, which in some embodiments may provide improved touch sensitivity (e.g., ability to sense a lighter touch) and faster response time. Back shields are sometimes used in conjunction with other noise reduction approaches, including spacing apart touch panel 112 and a display, as noise strength from LCD displays, for example, rapidly decreases over distance. In addition to these techniques, other approaches to dealing with noise problems are discussed in reference to various embodiments, below.

The capacitive coupling between a given row and column electrode is primarily a function of the geometry of the electrodes in the region where the electrodes are closest together. Such regions correspond to the “nodes” of the electrode matrix, some of which are labeled in FIG. 1. For example, capacitive coupling between column electrode 116a and row electrode 118d occurs primarily at node 122, and capacitive coupling between column electrode 116b and row electrode 118e occurs primarily at node 124. The 5×5 matrix of FIG. 1 has 25 such nodes, any one of which can be addressed by controller 114 via appropriate selection of one of the control lines 126, which individually couple the respective column electrodes 116a-e to the controller, and appropriate selection of one of the control lines 128, which individually couple the respective row electrodes 118a-e to the controller.

When a finger 130 of a user or other touch implement comes into contact or near-contact with the touch surface of the device 110, as shown at touch location 131, the finger capacitively couples to the electrode matrix. The finger capacitively couples to the matrix, and draws charge away from the matrix, particularly from those electrodes lying closest to the touch location, and in doing so it changes the coupling capacitance between the electrodes corresponding to the nearest node(s). For example, the touch at touch location 131 lies nearest the node corresponding to electrodes 116c/118b. As described further below, this change in coupling capacitance can be detected by controller 114 and interpreted as a touch at or near the 116a/118b node. Preferably, the controller is configured to rapidly detect the change in capacitance, if any, of all of the nodes of the matrix, and is capable of analyzing the magnitudes of capacitance changes for neighboring nodes so as to accurately determine a touch location lying between nodes by interpolation. Furthermore, the controller 114 advantageously is designed to detect multiple distinct touches applied to different portions of the touch device at the same time, or at overlapping times. Thus, for example, if another finger 132 touches the touch surface of the device 110 at touch location 133 simultaneously with the touch of finger 130, or if the respective touches at least temporally overlap, the controller is preferably capable of detecting the positions 131, 133 of both such touches and providing such locations on a touch output 114a. The controller 114 preferably employs a variety of circuit modules and components that enable it to rapidly determine the coupling capacitance at some or all of the nodes of the electrode matrix, and there from determine the occurrence of contacts made to the surface of the touch panel.

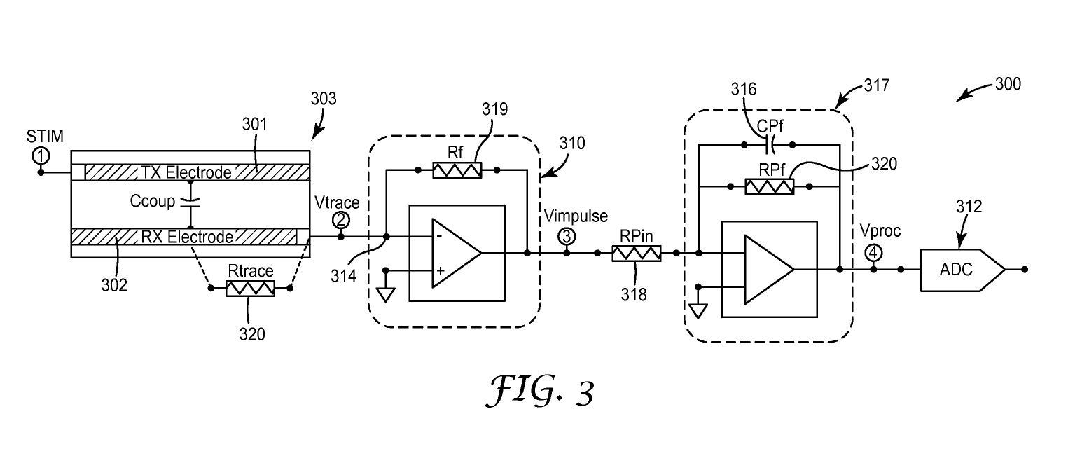

Turning now to FIG. 2, we see there a schematic side view of a portion of a touch panel 210 for use in a touch device. The panel 210 includes a front layer 212, first electrode layer 214 comprising a first set of electrodes, insulating layer 216, second electrode layer 218 comprising a second set of electrodes 218a-e preferably orthogonal to the first set of electrodes, and a rear layer 220. The exposed surface 212a of layer 212, or the exposed surface 220a of layer 220, may be or comprise the touch surface of the touch panel 210. FIG. 3 is a schematic of electrode testing system 300. A representative node of touch panel 303 is shown, the portion comprising a driven electrode 301 and a receive electrode 302, with capacitive coupling Ccoup between them. Driven electrode 301 is physically electrically coupled to a signal generator (not shown in FIG. 3) which provides a stimulating signal. The stimulating signal capacitively couples to receive electrode 302, to provide Vtrace signal to amplifier circuit 310. Amplifier circuitr 310 is commercially available from Texas Instruments (product number OPA4134: ultra-low distortion, low noise.

Typically, a further resistor, sometimes referred to as an input resistor, would precede virtual ground node 314 (i.e., a further resistor would be positioned immediately to the left of virtual ground node 314). The function of such input resistor is, among other things, to isolate amplifier 310 from the electrode. It has been discovered, however, that by removing this input resistor, or making it significantly small, the resistance of the measured trace Rtrace 320 can be fed directly into the virtual ground node 311. Significantly small, as such term is used herein, means small enough that the resultant signal from the virtual ground amplifier has characteristics that are a function of the resistance of the electrode. The resultant signal is a combination of the coupled drive, or stimulating, signal and the electrode resistance. Ideally amplifier circuit 310 normalizes to ground whatever signal is provided to amplifier circuit 310. In real world conditions, however, the virtual grounding circuit is not ideal, and there is a small but important impulse signal Vimpluse produced by amplifier circuit 310. This signal is the result of amplifier circuit 310 attempting to ground out the signal provided to it; or, in other words, amplifier 310 is brings the signal Vtrace to a ground potential, which causes what little energy that was coupled into Rtrace to be forced to zero. This transforms the original coupled energy into an impulse event. Since the resistivity of the trace (Rtradce 320) is coupled, along with the feedback resistance Rf 319, to the virtual ground node, the peak of the resulting waveform Vimpulse is a linear function of the resistance of the trace. Thus, the peak of the resulting impulse will vary as a linear function of the resistance of electrode. It would be expected that shorting the signal Vtrace to ground would result in a signal with such low energy content that shorting it to ground would not leave any measurable or useful signal content. However, it has been discovered that there is enough energy in the resulting impulse signal Vimpulse that it is possible to extract a stable signal with significant content. Note that Rtrace 320 has dashed lines pointing to the capacitive coupling stimulation point of the Rx electrode 302 (left dashed line) and the right end of the Rx electrode 302, where electrode testing system 300 would be physically electrically coupled to RX electrode 302, either directly or via a tail or other circuitry. It is the resistivity of the electrode between these two points that is of being quantified by the electrode testing system. Physically electrically coupled, as such term is used herein, refers to physical (as opposed to mere capacitive) coupling of components. For example, conductors physically couple components of a circuit to one another.

Due to the low signal level of the impulse signal Vimpulse, a secondary gain stage amplification is applied to the signal. Amplifier circuit 320 is thus used to further condition and amplify the impulse signal Vimpulse resulting from amplifier circuit 310, to produce signal Vproc, which is then digitized by analog-to-digital converter (ADC) 312. Amplifier circuit 310 is a low pass filter from where CPf is used to limit the frequency content of the generated signal, effectively filtering out high frequency noise. Different sensor types will generate different peak voltage levels Resistor 317 and resistor 318 are chosen to scale the resulting signal Vproc into the full dynamic range of ADC 312, increasing signal to noise of the resulting signal. Once digitized by ADC 312, the signal is further processed, one manner of such further processing including peak detection of the resulting signal. Relative resistance measurements of the trace may be inferred by correlating it with the relative size of the detected peak. If actual resistance measurements (as opposed to relative) are desired, a calibration formula or lookup table may be used that associates a measured signal peak with the resistance of a given trace/touch panel design. Generally, it is assumed there is uniform spacing between capacitively coupled electrodes of the upper and lower electrode arrays.

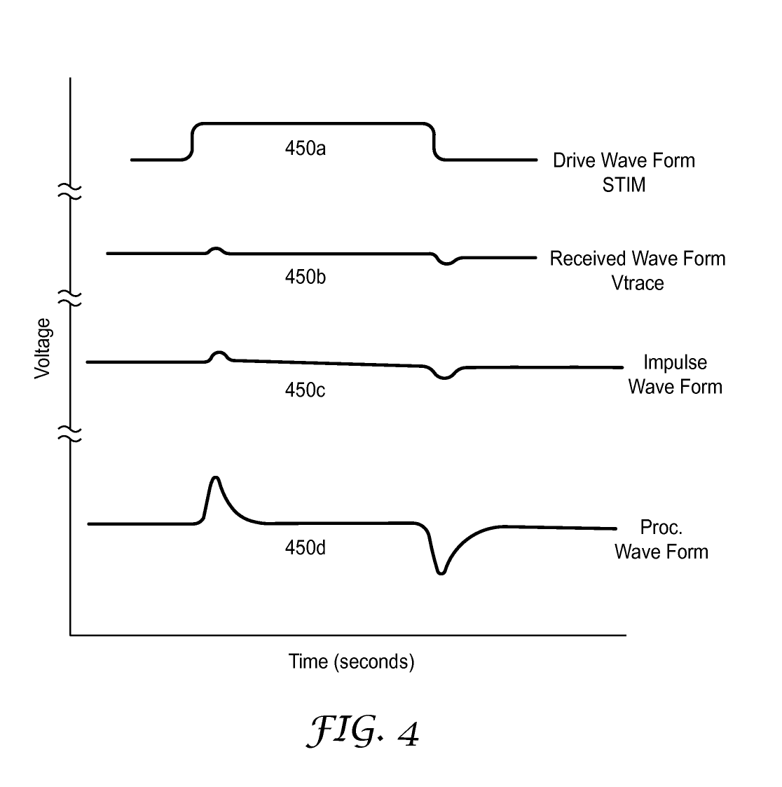

FIG. 4 shows representative waveforms occurring at various positions along testing system 300 for the evaluation of an electrode on touch panel 303. Particularly, drive waveform 450a (STIM) is shown at position 1 in FIG. 3. The drive waveform is a square wave having peak values consistent with transistor-transistor logic (TTL) level outputs, usually in range of 3.3-5 volts. The received waveform 450b (VTRACE), occurring at position 2 in FIG. 3, is a weak signal, on the order of 2 millivolts. Noise levels occurring at position 2 will routinely exceed this signal level, but such noise has a higher frequency content and is filtered out by the low pass filter. Impulse waveform 450c, occurring at measurement position 3 in FIG. 3, is on the order of about 200 millivolts. After the amplification/filtering stage (amplifier 320), the resulting PROC waveform 450d is shown as occurring at measurement point 4. It is the PROC waveform that is digitized by ADC 312, then peak detected. The peak detected waveform may then be used as-is for relative measurements, or converted into ohms by means of an equation and/or a lookup table.

Testing system 300 may be incorporated into a touch panel testing apparatus. Such an apparatus may be used to test electrodes in mutual-capacitive based touch panels for abnormal resistivity. Such testing is typically only possible with physical electrical access to both ends of an electrode, and modern touch panels may provide such physical electrical access to only one end of a touch panel electrode. That is, for one of the two arrays of electrodes that comprise most modern mutual capacitive touch panels (typically upper and lower arrays separated by a dielectric), a tail is typically electrically coupled to both arrays, and often just one end of both arrays—i.e., there is only the possibility of physical electrical coupling to the tail side of the electrode; the other side is buried. Some touch panels do, however, have tails on both ends of electrodes of either the upper or lower arrays (or sometimes both the upper and the lower). In such panels that have physical electrical access to both sides of the electrode, the above described measurements system may still be advantageously used to measure resistivity. This is because the use of a standard resistance measurement technique, by connecting to both sides of an electrode, can only provide a total resistance measurement of the electrode under test. The inferred measurement produced through capacitive coupled events, as described herein, allow measurement of resistance at any point in the electrode, but particularly at node points. Such ability to measure at any point along the electrode can be important, because electrodes may exhibit correct total resistance but show poor resistance distribution, which will lead to poorly functioning touch panels.

1. An apparatus for inferring the resistivity of an electrode between a stimulation point and a measurement point, wherein a drive signal is introduced into the electrode at the stimulation point by capacitive coupling, and the measurement point is physically electrically coupled to a measurement circuitry comprising an amplifier circuit configured to produce a resultant signal that is a function of the resistivity of the electrode.

2. The apparatus of claim 1, wherein the amplifier circuit comprises a virtual ground amplifier having a virtual ground node, and wherein the measured trace is directly physically electrically coupled to the virtual ground node.

3. The apparatus of claim 2, wherein directly physically electrically coupled comprises the absence of a resistor between the measurement point of the electrode and the virtual ground node.

4. The apparatus of claim 2, wherein directly physically electrically coupled comprises a significantly small resistor is between the measurement point of the electrode and the virtual ground node.

5. The apparatus of claim 2, wherein the resultant signal's amplitude is a function of the resistivity of the electrode.

6. The apparatus of claim 5, wherein the resultant signal's amplitude is a linear function of the resistivity of the electrode.

7. The apparatus of claim 2, further comprising an analog-to-digital converter coupled to the amplifier circuit to process the resultant signal.

8. The apparatus of claim 2, further comprising a peak detector for detecting the peak voltage of the resultant signal.

9. The apparatus of claim 7, further comprising a low-pass amplifier circuit between the analog-to-digital converter and the amplifier circuit.

10. A touch panel testing device that determines a resistivity for at least some of the electrodes in a mutual capacitive touch panel having a first and second array of electrodes separated by a dielectric and configured such that electrical signals applied an electrode of either array capacitively couple to the electrodes of the other array, comprising:
a drive signal generator electrically coupled to an electrode of the first array;
a measurement circuit physically electrically coupled to at lease one electrode of the second array, the measurement circuit comprising:
a virtual ground amplifier having a virtual ground node, wherein the virtual groud node is physically electrically coupled to the at least one electrode.

11. The touch panel testing device of claim 10, wherein physically electrically coupled comprises the absence of a resistor between the at least one electrode and the virtual ground node.

12. The touch panel testing device of claim 10, wherein directly physical electrical coupled comprises analog circuitry consisting only of one or more significantly small resistors between the virtual ground node and the at least one electrode.
